(19) United States
(12) Patent Application Publication
(10) Pub. No.: US 2014/0346446 A1
(43) Pub. Date: Nov. 27, 2014

(54) IRIDIUM COMPLEX AND ORGANIC LIGHT EMITTING DIODE USING THE SAME

(71) Applicant: National Tsing Hua University, Hsinchu (TW)

(72) Inventors: Chien-Hong CHENG, Hsinchu (TW); Tsu-Hui SU, Hsinchu (TW)

(73) Assignee: National Tsing Hua University, Hsinchu (TW)

(21) Appl. No.: 13/972,287

(22) Filed: Aug. 21, 2013

(30) Foreign Application Priority Data
May 21, 2013 (TW) 102117843

(51) Int. Cl. H01L 51/00

(52) U.S. Cl. CPC H01L 51/0085
USPC 257/40; 546/4

(57) ABSTRACT

An iridium complex having at least two 2-(thiophen-2-yl)quinolone ligands is provided. The iridium complex of the present invention may be configured as host material or dopant in organic light emitting diode devices. The optoelectronic element of the present invention is provided with advantages such as high efficiency, high brightness, high color saturation and good thermal and chemical stability so as to improve the performance of organic light emitting diode devices.

### BACKGROUND OF THE INVENTION

1. Field of the Invention

The present invention relates to iridium complexes and organic light emitting diodes using the same, particularly relates to an iridium complexes having 2-(thiophen-2-yl)quinolone ligand) and organic light emitting diodes using the same.

2. Description of the Prior Art

OLED is composed of organic materials and semiconductor materials. OLED works on the mechanism that electrons and holes diffuse through an electron transport layer (ETL) and hole transport layer (HTL) respectively to enter a light-emitting layer, and recombine in the emitting region to form excitons. When excitons fall to the ground state, energy is given off in the form of photo radiation. The radiation color can be tuned by applying different emitting materials. OLED has been spotlighted due to a lot of advantages, such as self illumination, wider visual angle (>170°), shorter response time (˜μs), higher contrast, higher efficiency, lower power consumption, higher brightness, lower operative voltage (3-10V), thinner size (<2 mm), flexibility and so on.

Excitons generated from recombining holes and electrons have triplet state or singlet state for its spin state. Singlet exciton relaxation radiates fluorescence and triplet exciton relaxation radiates phosphorescence. Phosphorescence achieves 3-fold efficiency comparing to fluorescence and may greatly enhance the IQE (internal quantum efficiency) of devices up to 100% by adopting metal complexes in electroluminescent configuration to achieve strong spin-orbital coupling and mixing of singlets and triplets. Therefore, phosphorescent metal complexes are now adopted as phosphorescent dopants in the emitting layer of OLED.

The light emitting layer is usually formed by doping process, namely doping phosphorescent materials into luminescent materials. Thanks to the introduction of phosphorescent material, the internal conversion efficiency of the organic light-emitting diodes can be increased to 100%, and therefore the development of new high-efficiency phosphorescent material is currently a mainstream. Among those materials, iridium complexes play an important role. Reported by previous researches, there were synthesized iridium complexes provided with phenylquinoline or phenylisoquinoline ligands and achieving good efficiency when applied in PHOLED (phosphorescent OLED) devices. However, there are only few materials that have been reported to achieve high external quantum efficiency, current efficiency and energy efficiency in red phosphorescent organic light emitting devices.

U.S. Patent Application No. US20050025995, for example, disclosed following compounds and synthesis and application of iridium complexes having at least two 2-(thiophen-2-yl) quinolone ligands.

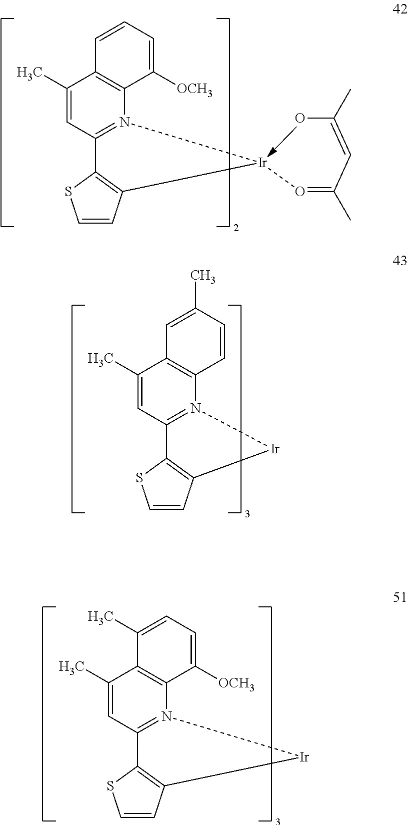

In summary, it is now a current goal to discover luminescent materials that may reach high external quantum efficiency, current efficiency and energy efficiency in red phosphorescent OLED devices.

To sum up, it is an important issue to develop a novel host material to be applied in OLED.

### SUMMARY OF THE INVENTION

The present invention is directed to providing novel compounds that are capable of achieving high external quantum efficiency, current efficiency and energy efficiency in red phosphorescent OLED devices.

According to one embodiment of the present invention, an iridium complex is represented by formula (1):

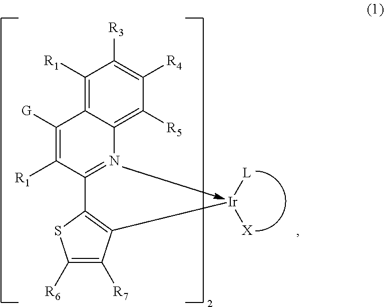

wherein groups L and X are linked in an arch to form a ligand represented by Ar₁-Ar₂, L is N or O and X is C, N or O, Ar₁ is a non-substituted or substituted N-heterocyclic ring, Ar₂ is a non-substituted or substituted aromatic ring, a non-substituted or substituted N-heterocyclic ring or a non-substituted or substituted S-heterocyclic ring, or Ar₁ and Ar₂ together are

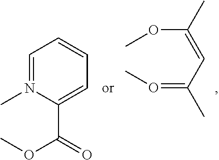

wherein each of substituents of Ar₁ and Ar₂, G, R₁ to R₇ is a member independently selected from the group consisting of H, halo, cyano, amino, substituted or non-substituted C₁-C₁₀ alkyl, substituted or non-substituted C₂-C₁₀ alkenyl, substituted or non-substituted C₂-C₁₀ alkynyl, substituted or non-substituted C₃-C₂₀ cycloalkyl, substituted or non-substituted C₃-C₂₀ cycloalkenyl, substituted or non-substituted C₁-C₂₀ heterocycloalkyl, substituted or non-substituted C₁-C₂₀ heterocycloalkenyl, substituted or non-substituted aryl and substituted or non-substituted heteroaryl and wherein at least one of R₆ and R₇ is not hydrogen.

The present invention is also directed to providing an organic light emitting diode with high efficiency and device performance.

According to another embodiment of the present invention, an organic light emitting diode comprising a cathode, an anode and a light-emitting layer arranged between the anode and the cathode. The light-emitting layer comprises the aforementioned iridium complex.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

FIG. 1 is a schematic diagram illustrating the structure of an organic light-emitting diode using the iridium complex.

### DESCRIPTION OF THE PREFERRED EMBODIMENT

The iridium complex of the present invention is presented by formula (1):

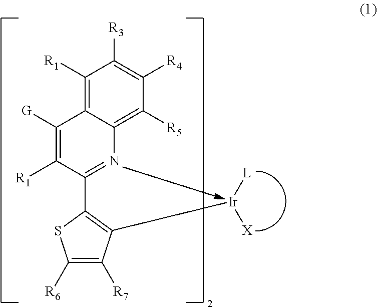

Groups L and X are linked in an arch to form a ligand represented by Ar₁-Ar₂, L is N or O and X is C, N or O, Ar₁ is a non-substituted or substituted N-heterocyclic ring, Ar₂ is a non-substituted or substituted aromatic ring, a non-substituted or substituted N-heterocyclic ring or a non-substituted or substituted S-heterocyclic ring, or Ar₁ and Ar₂ together are

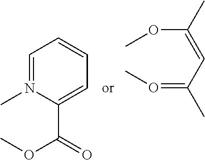

The above-mentioned aromatic ring includes without limitations to benzene or naphthalene. N-heterocyclic ring includes without limitations to pyrrole, pyridine, or quinoline. S-heterocyclic ring includes without limitations to thiophene or thiopyran.

Examples of ĈN and N̂N ligands are listed as followings. Other example and synthesis protocol of ĈN and N̂N ligands has been listed in US patent application No. 20110313161 of Chi et al. and hence may be incorporated by reference.

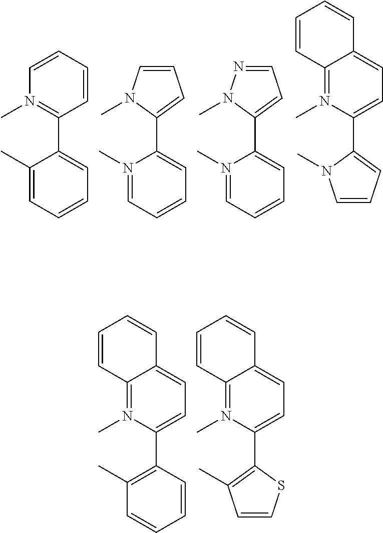

In one embodiment, the iridium complex of the present invention is presented by formula (2) or (3), namely Ar₁-Ar₂ together is ĈN or ÔO ligands.

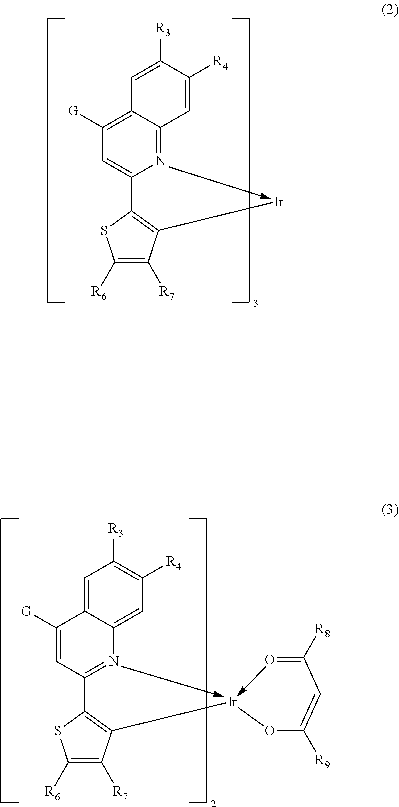

The substituents in the iridium complex of the present invention, such as G, R₁ to R₉ or substituents of Ar₁ and Ar₂ are independently selected from the group consisting of H, halo, cyano, amino, substituted or non-substituted C₁-C₁₀ alkyl, substituted or non-substituted C₂-C₁₀ alkenyl, substituted or non-substituted C₂-C₁₀ alkynyl, substituted or non-substituted C₃-C₂₀ cycloalkyl, substituted or non-substituted C₃-C₂₀ cycloalkenyl, substituted or non-substituted C₁-C₂₀ heterocycloalkyl, substituted or non-substituted C₁-C₂₀ heterocycloalkenyl, substituted or non-substituted aryl and substituted or non-substituted heteroaryl.

It is noted that at least one of R₆ and R₇ is not hydrogen. Here, at least one of R₆ and R₇ is selected from a group consisting of substituted or non-substituted C₁-C₁₀ alkyl, substituted or non-substituted C₂-C₁₀ alkenyl, substituted or non-substituted C₂-C₁₀ alkynyl, and substituted or non-substituted aryl. Preferably, at least one of R₆ and R₇ is selected from a group consisting of substituted or non-substituted C₁-C₁₀ alky and substituted or non-substituted phenyl group.

The term “aryl” refers to a hydrocarbon moiety having one or more aromatic rings. Examples of aryl moieties include phenyl (Ph), phenylene, naphthyl, naphthylene, pyrenyl, anthryl, and phenanthryl.

The term “heteroaryl” refers to a moiety having one or more aromatic rings that contain at least one heteroatom (e.g., N, O, or S). Examples of heteroaryl moieties include furyl, furylene, fluorenyl, pyrrolyl, thienyl, oxazolyl, imidazolyl, thiazolyl, pyridyl, pyrimidinyl, quinazolinyl, quinolyl, isoquinolyl and indolyl.

Alkyl, alkenyl, alkynyl, cycloalkyl, cycloalkenyl, heterocycloalkyl, heterocycloalkenyl, aryl, and heteroaryl mentioned herein include both substituted and non-substituted moieties, unless specified otherwise. Possible substituents on cycloalkyl, cycloalkenyl, heterocycloalkyl, heterocycloalkenyl, aryl, and heteroaryl include, but are not limited to, C₁-C₁₀ alkyl, C₂-C₁₀ alkenyl, C₂-C₁₀ alkynyl, C₃-C₂₀ cycloalkyl, C₃-C₂₀ cycloalkenyl, C₁-C₂₀ heterocycloalkyl, C₁-C₂₀ heterocycloalkenyl, C₁-C₁₀ alkoxy, aryl, aryloxy, heteroaryl, heteroaryloxy, amino, C₁-C₁₀ alkylamino, C₁-C₂₀ dialkylamino, arylamino, diarylamino, C₁-C₁₀ alkylsulfonamino, arylsulfonamino, C₁-C₁₀ alkylimino, arylimino, C₁-C₁₀ alkylsulfonimino, arylsulfonimino, hydroxyl, halo, thio, C₁-C₁₀ alkylthio, arylthio, C₁-C₁₀ alkylsulfonyl, arylsulfonyl, acylamino, aminoacyl, aminothioacyl, amido, amidino, guanidine, ureido, thioureido, cyano, nitro, nitroso, azido, acyl, thioacyl, acyloxy, carboxyl, and carboxylic ester. On the other hand, possible substituents on alkyl, alkenyl, or alkynyl include all of the above-recited substituents except C₁-C₁₀ alkyl. Cycloalkyl, cycloalkenyl, heterocycloalkyl, heterocycloalkenyl, aryl, and heteroaryl can also be fused with each other.

Examples of some iridium complexes according to the present invention are listed in the following; however, it is understood that the present invention is not thus limited to those complexes.

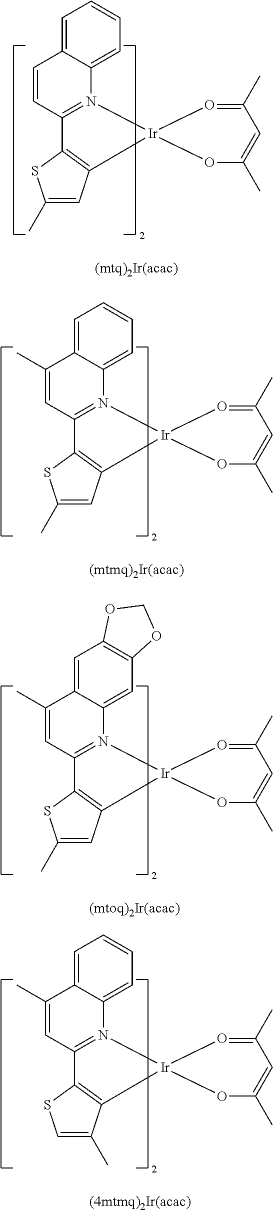

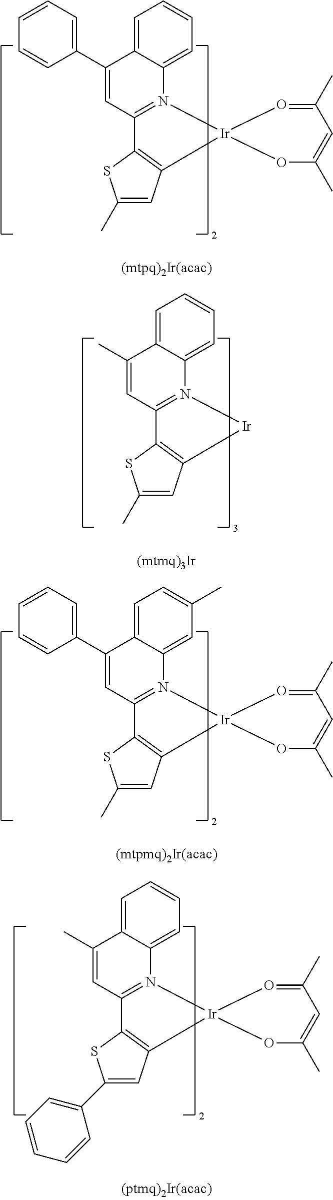

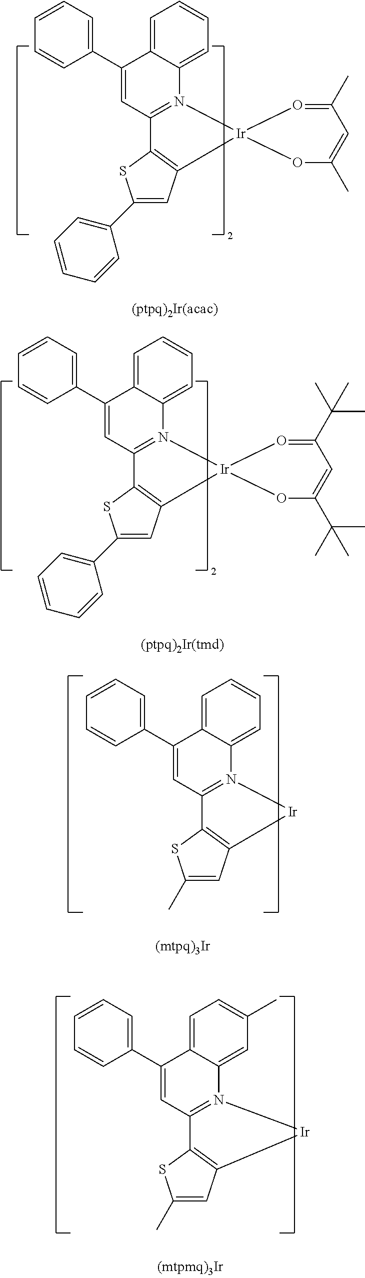

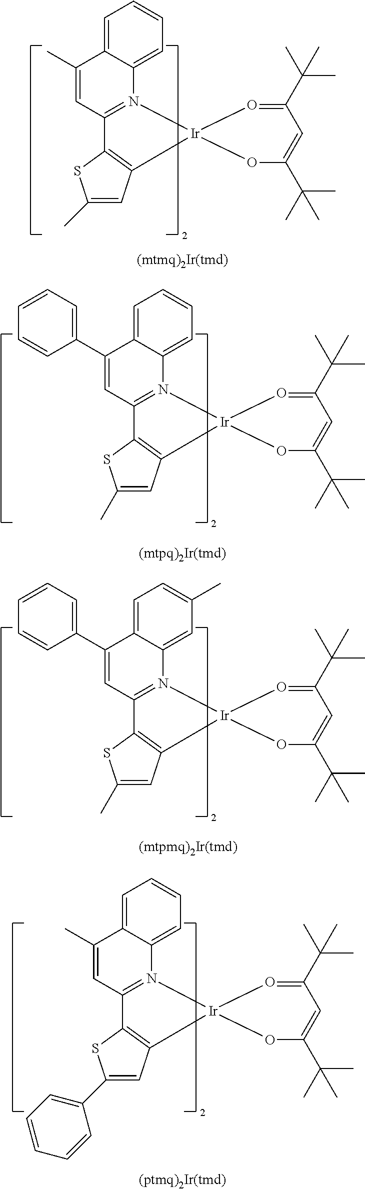

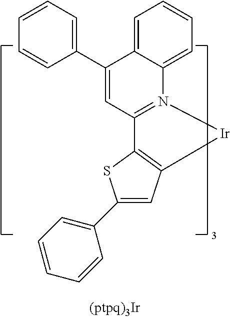

### Compound Synthesis

Referring to the following reaction formula, the iridium complexes of the present invention is synthesized according to the following reaction formula.

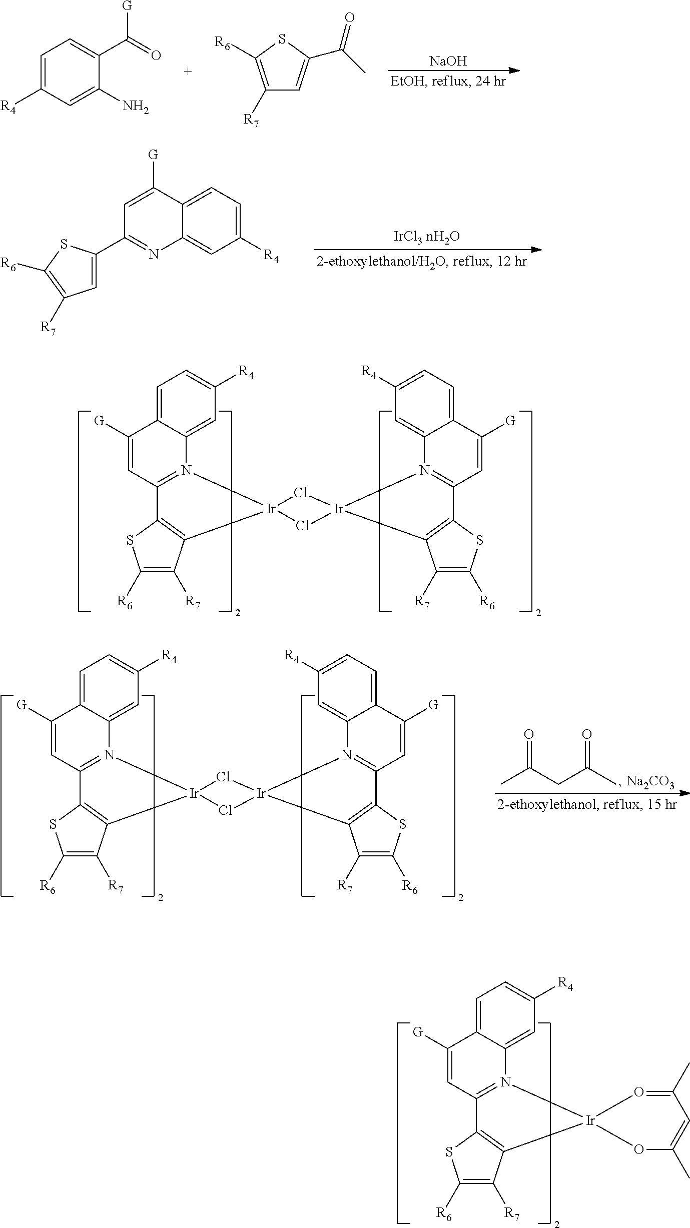

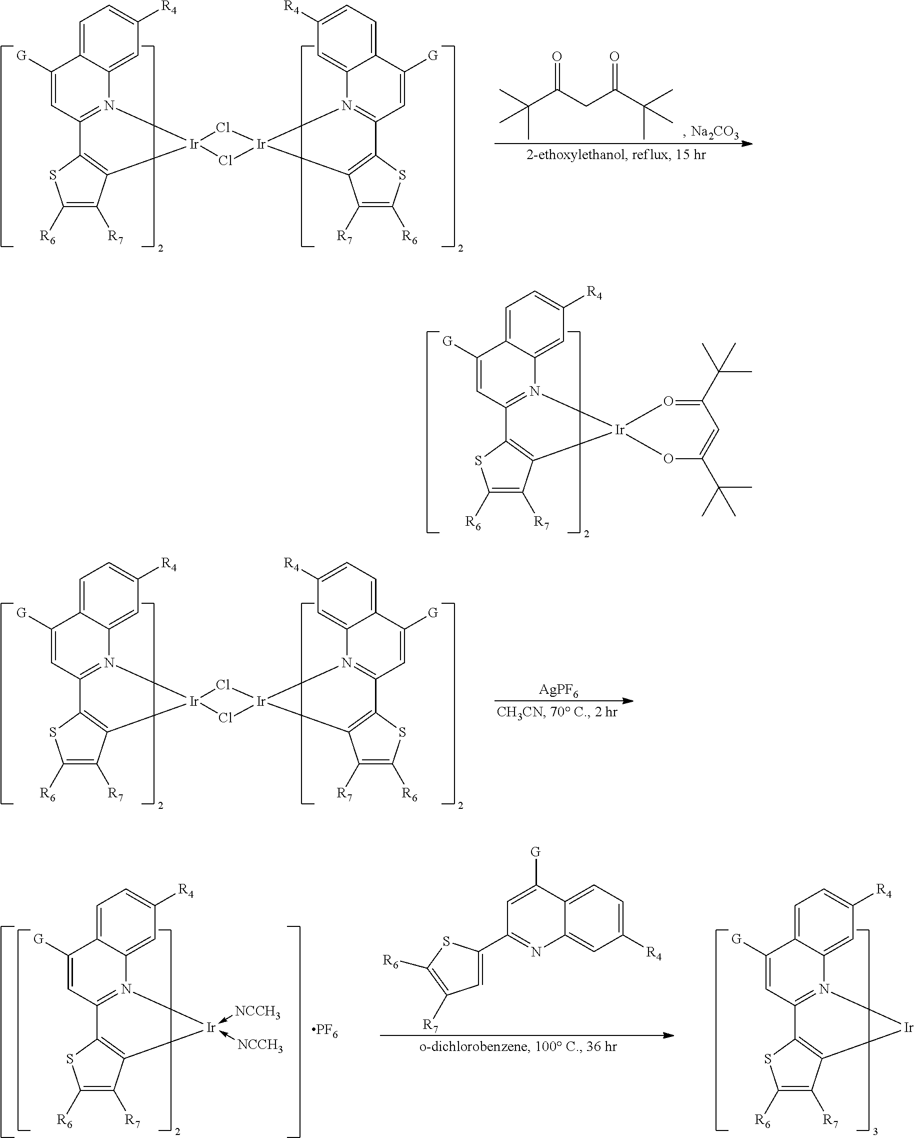

It is noted that various iridium complexes may be obtained by adjusting another ligands besides 2-(thiophen-2-yl)quinolone ligands. Some synthesis steps and spectral data of specific examples of the present invention are listed as following.

### a. Synthesis of Ligand:

### 2-(thiophen-2-yl)quinoline derivatives

2-acetylthiophene and 2-aminoacetophenone derivative were respectively taken and placed in a sealed tube. 25 ml a saturated solution of sodium hydroxide in ethanol was added, heated to 80° C. for reaction with stirring for one day. After completion of the reaction and cooling, ethanol was removed with a rotating concentrator so as to obtain a thick, pale yellow crude product. The crude product was dissolved in 50 ml ethyl acetate and extracted twice with 100 ml water. The organic layer was collected and added with magnesium sulfate for dehydration, subjected to a rotating concentrator to remove ethyl acetate and further purified using column chromatography with ethyl acetate: n-hexane=1:10.

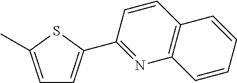 [SMILES: Cc1ccc(-c2ccc3ccccc3n2)s1]

### 2-(5-methylthiophen-2-yl) quinoline (mtq)

The synthesis was achieved by the above experimental method using 2-acetyl-5-methylthiophene (2.10 g, 15.0 mmol) and 2-aminobenzaldehyde(1.82 g, 15.0 mmol) to obtain 2.50 g white solid, yield=74%.

¹H NMR (400 MHz, CDCl₃, δ): 8.06-8.04 (m, 2H), 7.73-7.69 (m, 2H), 7.66 (t, J=7.6 Hz, 1H), 7.50 (d, J=3.2 Hz, 1H), 7.44 (t, J=7.6 Hz, 1H), 6.80 (s, 1H), 2.54 (s, 3H); ¹³C NMR (100 MHz, CDCl₃, δ): 152.48, 148.08, 143.58, 142.84, 163.33, 129.64, 129.09, 127.39, 126.94, 126.38, 125.96, 125.75, 117.27, 15.70; HRMS (FAB, m/z): [M⁺] calcd for C₁₄H₁₁NS, 225.0612. found 225.0616.

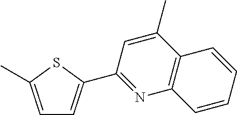 [SMILES: Cc1ccc(-c2cc(C)c3ccccc3n2)s1]

### 4-methyl-2-(5-methylthiophen-2-yl)quinoline (mtmq)

The synthesis was achieved by the above experimental method using 2-acetyl-5-methylthiophene, 2.10 g, 15.0 mmol) and 2-aminoacetophenone (2.03 g, 15 mmol) to obtain 2.85 g white solid, yield=80%.

¹H NMR (400 MHz, CDCl₃, δ): 8.07 (d, J=8.4 Hz, 1H), 7.83 (d, J=8.0 Hz, 1H), 7.64 (t, J=7.2 Hz, 1H), 7.49 (s, 1H), 7.46 (d, J=3.2 Hz, 1H), 7.42 (t, J=7.6 Hz, 1H), 6.78 (s, 1H), 2.61 (s, 3H), 2.53 (s, 3H); ¹³C NMR (100 MHz, CDCl₃, δ): 151.97, 147.75, 144.18, 143.11, 142.84, 129.44, 129.14, 126.94, 126.21, 125.65, 125.34, 123.41, 117.68, 18.64, 15.57; HRMS (FAB, m/z): [M⁺] calcd for C₁₅H₁₃NS, 239.0769. found 239.0776.

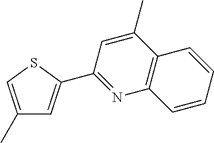 [SMILES: Cc1csc(-c2cc(C)c3ccccc3n2)c1]

### 4-methyl-2-(4-methylthiophen-2-yl)quinoline (4mtmq)

The synthesis was achieved by the above experimental method using 2-acetyl-4-methylthiophene (2.10 g, 15.0 mmol) and 2-aminoacetophenone (2.03 g, 15 mmol to obtain 2.57 g white solid, yield=72%.

¹H NMR (400 MHz, CDCl₃, δ): 8.07 (d, J=8.4 Hz, 1H), 7.87 (d, J=8.0 Hz, 1H), 7.65 (t, J=7.6 Hz, 1H), 7.53 (d, J=7.6 Hz, 2H), 7.45 (t, J=7.6 Hz, 1H), 7.02 (s, 1H), 2.65 (s, 3H), 2.30 (s, 3H); ¹³C NMR (100 MHz, CDCl₃, δ): 151.93, 147.83, 144.86, 144.44, 138.52, 129.66, 129.27, 127.92, 127.16, 125.61, 123.75, 123.49, 118.09, 18.75, 15.79; HRMS (FAB, m/z): [M⁺] calcd for C₁₅H₁₃NS, 239.0769. found 239.0776.

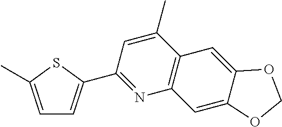 [SMILES: Cc1ccc(-c2cc(C)c3cc4c(cc3n2)OCO4)s1]

### 8-methyl-6-(5-methylthiophen-2-yl)-[1,3]dioxolo[4,5-g]quinoline(mtoq)

The synthesis was achieved by the above experimental method using 2-acetyl-5-methylthiophene, 2.10 g, 15.0 mmol) and 2-Amino-4,5-methylenedioxyacetophenone (2.69 g, 15.0 mmol) to obtain 3.29 g white solid, yield=77%.

¹H NMR (400 MHz, CDCl₃, δ): 7.42 (d, J=3.6 Hz, 1H), 7.42 (s, 1H), 7.33 (s, 1H), 7.16 (s, 1H), 6.76 (dd, J=0.8 Hz, J=3.6 Hz, 1H), 6.07 (s, 2H), 2.58 (s, 3H), 2.52 (s, 3H); ¹³C NMR (100 MHz, CDCl₃, δ): 150.28, 150.16, 147.18, 146.02, 143.02, 142.92, 142.33, 126.16, 124.77, 123.56, 116.37, 106.11, 101.51, 99.36, 19.19, 15.62; HRMS (FAB, m/z): [M⁺] calcd for C₁₆H₁₃NO₂S, 2383.0667. found 283.0659.

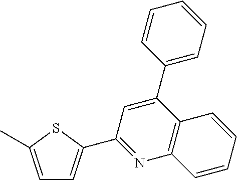 [SMILES: Cc1ccc(-c2cc(-c3ccccc3)c3ccccc3n2)s1]

### 2-(5-methylthiophen-2-yl)-4-phenylquinoline (mtpq)

The synthesis was achieved by the above experimental method using 2-acetyl-5-methylthiophene (2.10 g, 15.0 mmol) and 2-aminobenzophenone (2.96 g, 15.0 mmol) to obtain 3.73 g white solid, yield 83%.

¹H NMR (400 MHz, CDCl₃, δ): 8.10 (d, J=8.8 Hz, 1H), 7.80 (d, J=8.4 Hz, 1H), 7.68-7.64 (m, 2H), 7.53-7.51 (m, 6H), 7.39 (td, J=0.8 Hz, J=8.0 Hz, 1H), 6.79 (dd, J=0.8 Hz, J=3.6 Hz, 1H), 2.30 (s, 3H); ¹³C NMR (100 MHz, CDCl₃, δ): 151.98, 148.68, 148.57, 143.53, 142.84, 138.16, 129.46, 129.42, 128.49, 128.32, 126.37, 125.97, 125.76, 125.55, 117.48, 15.69; HRMS (FAB, m/z): [M⁺] calcd for C₂₀H₁₅NS, 301.0925. found 301.0932.

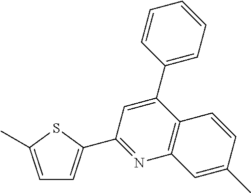

### 7-methyl-2-(5-methylthiophen-2-yl)-4-phenylquinoline (mtpmq)

The synthesis was achieved by the above experimental method using 2-acetyl-5-methylthiophene (2.10 g, 15.0 mmol) and 2-amino-4-methylbenzophenone (3.17 g, 15.0 mmol) to obtain 3.88 g white solid, yield=82%.

¹H NMR (400 MHz, CDCl₃, δ): 7.92 (s, 1H), 7.70 (d, J=8.4 Hz, 1H), 7.60 (s, 1H), 7.53-7.50 (m, 6H), 7.23 (dd, J=1.6 Hz, J=8.8 Hz, 1H), 6.79 (dd, J=0.8 Hz, J=3.6 Hz, 1H), 2.55 (s, 3H), 2.54 (s, 3H); ¹³C NMR (100 MHz, CDCl₃, δ): 151.98, 148.68, 148.57, 143.53, 142.84, 138.16, 129.46, 129.42, 128.49, 128.32, 126.37, 125.97, 125.76, 125.55, 117.48, 15.69; HRMS (FAB, m/z): [M⁺] calcd for C₂₁H₁₇NS, 315.1082. found 315.1087.

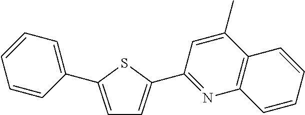 [SMILES: Cc1cc(-c2ccc(-c3ccccc3)s2)nc2ccccc12]

### 4-methyl-2-(5-phenylthiophen-2-yl)quinoline (ptmq)

The synthesis was achieved by the above experimental method using 1-(5-phenylthiophen-2-yl) ethanone (3.03 g, 15.0 mmol) and 2-aminoacetophenone (2.03 g, 15 mmol) to obtain a pale yellow solid product was 3.37 g, yield=74%.

¹H NMR (400 MHz, CDCl₃, δ): 8.14 (d, J=8.4 Hz, 1H), 7.83 (d, J=8.4 Hz, 1H), 7.72-7.66 (m, 3H), 7.57 (d, J=4.0 Hz, 1H), 7.48-7.38 (m, 4H), 7.33-7.24 (m, 2H), 2.57 (s, 3H); ¹³C NMR (100 MHz, CDCl₃, δ): 151.58, 147.69, 146.56, 144.29, 134.04, 129.44, 129.24, 128.75, 127.64, 126.44, 125.52, 123.78, 123.44, 117.59, 18.60; HRMS (FAB, m/z): [M⁺] calcd for C₂₀H₁₅NS, 301.0925. found 301.0921.

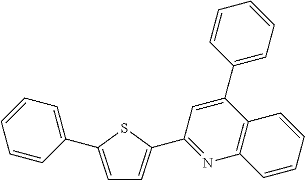 [SMILES: c1ccc(-c2ccc(-c3cc(-c4ccccc4)c4ccccc4n3)s2)cc1]

### 4-phenyl-2-(5-phenylthiophen-2-yl)quinoline (ptpq)

The synthesis was achieved by the above experimental method using 1-(5-phenylthiophen-2-yl) ethanone (3.03 g, 15.0 mmol) and 2-aminobenzophenone (2.96 g, 15.0 mmol) to obtain a pale yellow solid product was 3.70 g, yield=74%.

¹H NMR (400 MHz, CDCl₃, δ): 8.17 (d, J=8.4 Hz, 1H), 7.83 (d, J=8.4 Hz, 1H), 7.72-7.66 (m, 5H), 7.48-7.45 (m, 5H), 7.44-7.39 (m, 3H), 7.36 (d, J=4.0 Hz, 1H), 7.31 (t, J=7.6 Hz, 1H); ¹³C NMR (100 MHz, CDCl₃, δ): 151.68, 148.99, 148.56, 147.23, 138.10, 134.19, 129.72, 129.48, 128.94, 128.59, 128.47, 127.92, 126.89, 126.11, 125.81, 125.68, 124.03, 117.56; HRMS (FAB, m/z): [M⁺] calcd for C₂₅H₁₇NS, 363.1082. found 363.1081.

### b. Synthesis of Iridium Metal Complexes

The 2-(thien-2-yl) quinoline derivative was applied as a ligand (2.2 mmol) and placed in a sealed tube, Iridium (III) chloride (0.375 g, 1.0 mmol) was added and 2-ethoxyethanol and water were mixed at a ratio of 3:1 as a solvent (5 ml), reacted for 15 hours at 110° C. After completion of the reaction and cooled to room temperature, the solution was filtered using 10 ml water to collect solid, which was rinsed in a small amount of water and methanol, further rinsed with n-hexane for several times and pumped off to obtain orange to dark red solid of chloride-bridged iridium dimer complexes, where the yield was higher than 90%. The chloride-bridged iridium dimer complexes (0.3 mmol) was then placed in 5 ml reaction flask, sodium carbonate (0.42 g, 4.0 mmol) was added and 2,4-pentanedione (0.10 g, 1.0 mmol) or 2,2,6,6-Tetramethylheptane-3,5-dione (0.19 g, 1.0 mmol) as applied an auxiliary ligand. After mixing homogeneously, 5 ml 2-ethoxyethanol was used as a solvent to react for 12 hours at 80° C. After complete reaction and cooled to room temperature, the solution was filtered by adding 10 ml water to collect solid, which was rinsed with a small amount of water and methanol, further rinsed with n-hexane for several times and purified with column chromatography using dichloromethane:n-hexane in 1:1 ratio.

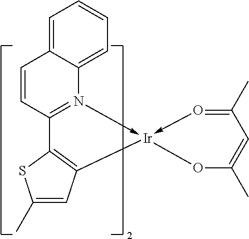

### Iridium(III) bis(2-(5-methylthiophen-2-yl)quinolinato-N,C^{2′}) acetylacetonate[(mtq)₂Ir(acac)]

dark red solid, yield=52%.

¹H NMR (400 MHz, CD₂Cl₂, δ): 8.27 (d, J=8.8 Hz, 2H), 8.05 (d, J=8.8 Hz, 2H), 7.76 (d, J=7.6 Hz, 2H), 7.58 (d, J=8.8 Hz, 2H), 7.51-7.47 (m, 2H), 7.43 (t, J=7.2 Hz, 2H), 5.92 (s, 2H), 4.94 (s, 1H), 2.36 (s, 6H), 1.67 (s, 6H); ¹³C NMR (100 MHz, CD₂Cl₂, δ): 186.24, 166.98, 155.61, 150.56, 146.18, 138.86, 138.26, 133.57, 131.11, 128.37, 126.03, 124.80, 116.85, 101.06, 28.32, 15.81; HRMS (FAB, m/z): [M+] calcd. for C₃₃H₂₇N₂O₂S₂Ir, 740.1143. found 740.1143. Anal. calcd for C₃₃H₂₇N₂O₂S₂Ir: N, 3.79, C, 53.57, H, 3.68, S, 8.67. found: N, 3.80, C, 53.42, H, 3.63, S, 8.60.

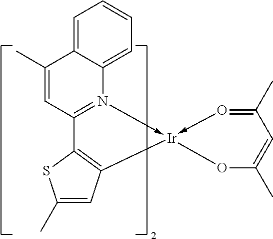

### Iridium(III) bis(2-(5-methylthiophen-2-yl)-4-methylquinolinato-N,C^{2′}) acetylacetonate[(mtmq)₂Ir(acac)]

dark red solid, yield=61%.

¹H NMR (400 MHz, CD₂Cl₂, δ): 8.29-8.27 (m, 2H), 7.93-7.90 (m, 2H), 7.51-7.43 (m, 3H), 5.90 (s, 2H), 4.94 (s, 1H), 2.86 (s, 6H), 2.35 (s, 6H), 1.66 (s, 6H); ¹³C NMR (100 MHz, CD₂Cl₂, δ): 186.11, 166.29, 155.07, 150.11, 147.15, 145.63, 138.24, 133.54, 130.69, 126.10, 125.25, 124.53, 124.43, 117.50, 100.98, 28.37, 19.07, 15.79; HRMS (FAB, m/z): [M+] calcd. for C₃₅H₃₁N₂O₂S₂Ir, 768.1456. found 768.1458. Anal. calcd for C₃₅H₃₁N₂O₂S₂Ir: N, 3.65, C, 54.74, H, 4.07, S, 8.35. found: N, 3.70, C, 54.66, H, 4.05, S, 8.29.

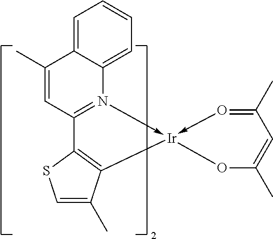

### Iridium(III) bis(2-(5-methylthiophen-2-yl)-4-methylquinolinato-N,C^{2′}) acetylacetonate[(4mtmq)₂Ir(acac)]

dark red solid, yield=55%.

¹H NMR (400 MHz, CD₂Cl₂, δ): 8.13-8.10 (m, 2H), 7.91-7.88 (m, 2H), 7.56 (s, 2H), 7.45-7.42 (m, 4H), 6.77 (s, 2H), 4.74 (s, 1H), 2.84 (s, 6H), 1.58 (s, 6H), 1.15 (s, 6H); ¹³C NMR (100 MHz, CD₂Cl₂, δ): 185.74, 166.52, 152.94, 150.01, 147.31, 147.20, 140.60, 130.55, 125.77, 125.28, 124.79, 124.44, 117.76, 100.27, 28.20, 19.13, 16.01; HRMS (FAB, m/z): [M+] calcd. for C₃₅H₃₁N₂O₂S₂Ir, 768.1456. found 768.1450. Anal. calcd for C₃₅H₃₁N₂O₂S₂Ir: N, 3.65, C, 54.74, H, 4.07. found: N, 3.60, C, 54.66, H, 4.01.

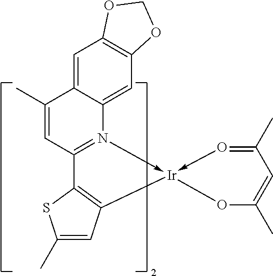

### Iridium(III) bis(8-methyl-6-(5-methylthiophen-2-yl)-[1,3]dioxolo[4,5-g]quinolinato-N,C^{2′})acetylacetonate[(mtoq)₂Ir(acac)]

red solid, yield=64%.

¹H NMR (400 MHz, CD₂Cl₂, δ): 7.87 (s, 2H), 7.31 (s, 2H), 7.21 (s, 2H), 6.06 (d, J=7.2 Hz, 4H), 5.86 (s, 2H), 5.04 (s, 1H), 2.76 (s, 6H), 2.35 (s, 6H), 1.67 (s, 6H); HRMS (FAB, m/z): [M+] calcd. for C₃₇H₃₁N₂O₆S₂Ir, 856.1253. found 856.1261.

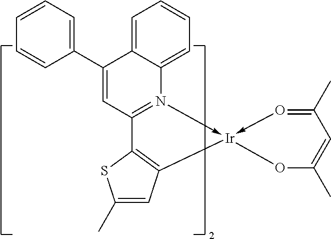

### Iridium(III) bis(2-(5-methylthiophen-2-yl)-4-phenylquinolinato-N,C^{2′})acetylacetonate[(mtpq)₂Ir(acac)]

dark red solid, yield=67%.

¹H NMR (400 MHz, CD₂Cl₂, δ): 8.38 (d, J=8.4 Hz, 2H), 7.81 (d, J=7.6 Hz, 2H), 7.67-7.54 (m, 12H), 7.50 (t, J=7.2 Hz, 2H), 7.38 (t, J=7.2 Hz, 2H), 6.02 (s, 2H), 5.01 (s, 1H), 2.38 (s, 6H), 1.73 (s, 6H); ¹³C NMR (100 MHz, CD₂Cl₂, δ): 186.31, 166.34, 155.56, 151.00, 146.17, 138.45, 137.97, 133.64, 130.90, 130.12, 129.10, 129.01, 126.65, 125.19, 124.75, 117.20, 101.12, 28.44, 15.86; HRMS (FAB, m/z): [M+] calcd. for C₄₅H₃₅N₂O₂S₂Ir, 892.1769. found 892.1769. Anal. calcd for C₄₅H₃₅N₂O₂S₂Ir: N, 3.14, C, 60.58, H, 3.95, S, 7.19. found: N, 3.12, C, 60.66, H, 3.93, S, 7.15.

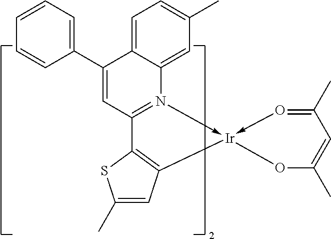

### Iridium(III) bis(7-methyl-2-(5-methylthiophen-2-yl)-4-phenyl quinolinato-N,C^{2′})acetylacetonate[(mtpmq)₂Ir(acac)]

dark red solid, yield=64%.

¹H NMR (400 MHz, CD₂Cl₂, δ): 8.26 (s, 2H), 7.69 (d, J=8.4 Hz, 2H), 7.65-7.54 (m, 10H), 7.46 (s, 2H), 7.24 (d, J=8.4 Hz, 2H), 5.99 (s, 2H), 5.10 (s, 1H), 2.44 (s, 6H), 2.38 (s, 6H), 1.75 (s, 6H); ¹³C NMR (100 MHz, CD₂Cl₂, δ): 186.06, 166.25, 154.76, 151.08, 150.82, 145.86, 141.44, 138.33, 138.14, 133.44, 130.10, 128.97, 126.78, 126.39, 124.62, 122.85, 116.39, 101.08, 94.20, 28.53, 22.20, 15.86; HRMS (FAB, m/z): [M+] calcd. for C₄₇H₃₉N₂O₂S₂Ir, 920.2082. found 920.2076. Anal. calcd for C₄₇H₃₉N₂O₂S₂Ir: N, 3.04, C, 61.35, H, 4.27, S, 6.97. found: N, 3.04, C, 61.14, H, 4.27, S, 6.97.

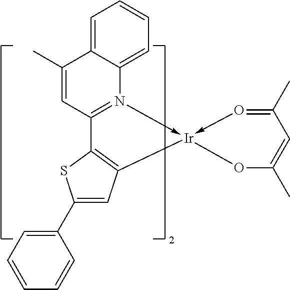

### Iridium(III) bis(4-methyl-2-(5-phenylthiophen-2-yl)quinolinato-N,C^{2′})acetylacetonate [(ptmq)₂Ir(acac)]

dark red solid, yield=54%.

¹H NMR (400 MHz, CD₂Cl₂, δ): 8.37-8.34 (m, 2H), 7.97-7.95 (m, 2H), 7.62 (s, 2H), 7.50-7.47 (m, 4H), 7.41-7.39 (m, 4H), 7.25-7.15 (m, 6H), 6.51 (s, 2H), 4.94 (s, 1H), 2.92 (s, 6H), 1.68 (s, 6H); ¹³C NMR (100 MHz, CD₂Cl₂, δ): 185.81, 165.74, 153.98, 149.67, 148.20, 147.15, 140.26, 134.22, 130.66, 130.55, 128.59, 127.73, 126.09, 125.06, 124.61, 124.17, 117.45, 100.60, 27.98, 18.81; HRMS (FAB, m/z): [M+] calcd. for C₄₅H₃₅N₂O₂S₂Ir, 892.1769. found 892.1775. Anal. calcd for C₄₅H₃₅N₂O₂S₂Ir: N, 3.14, C, 60.58, H, 3.95, S, 7.19. found: N, 3.14, C, 60.61, H, 3.93, S, 7.15.

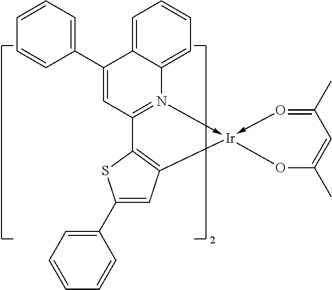

### Iridium(III) bis(2-(5-phenylthiophen-2-yl) 4-phenylquinolinato-N,C^{2′})acetylacetonate[(ptpq)₂Ir(acac)]

dark red solid, yield=52%.

¹H NMR (400 MHz, CD₂Cl₂, δ): 8.32-8.30 (m, 2H), 7.88-7.85 (m, 2H), 7.72-7.70 (m, 6H), 7.66-7.62 (m, 4H), 7.60-7.56 (m, 2H), 7.52-7.49 (m, 2H), 7.44-7.41 (m, 6H), 7.26-7.12 (m, 4H), 7.20-7.16 (m, 2H), 6.63 (s, 2H), 5.01 (s, 1H), 1.75 (s, 6H); ¹³C NMR (100 MHz, CD₂Cl₂, δ): 186.37, 166.18, 154.85, 151.26, 150.84, 149.03, 140.80, 137.91, 134.55, 131.13, 130.16, 129.22, 129.07, 129.00, 128.21, 126.77, 126.53, 125.39, 125.21, 118.66, 117.50, 101.11, 28.42; HRMS (FAB, m/z): [M+] calcd. for C₅₅H₃₉N₂O₂S₂Ir, 1016.2082. found 1016.2076. Anal. calcd for C₅₅H₃₉N₂O₂S₂Ir: N, 2.76, C, 65.00, H, 3.87, S, 6.31. found: N, 2.73, C, 64.90, H, 3.85, S, 6.27.

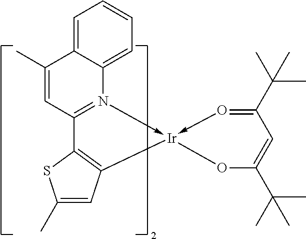

### Iridium(III) bis(2-(5-methylthiophen-2-yl)-4-methylquinolinato-N,C^{2′})tetramethylheptadionate[(mtmq)₂Ir(tmd)]

dark red solid, yield=58%.

¹H NMR (400 MHz, CD₂Cl₂, δ): 8.21 (d, J=8.4 Hz, 2H), 7.86 (d, J=8.4 Hz, 2H), 7.45 (s, 2H), 7.42-7.33 (m, 4H), 5.97 (s, 2H), 5.14 (s, 1H), 2.84 (s, 6H), 2.37 (s, 6H), 0.71 (s, 18H); ¹³C NMR (100 MHz, CD₂C₁₂, δ): 194.93, 166.28, 156.54, 150.03, 146.66, 145.09, 138.24, 133.78, 130.53, 125.73, 125.66, 124.27, 123.98, 117.30, 90.46, 40.89, 27.91, 19.00, 15.84; HRMS (FAB, m/z): [M+] calcd. for C₄₁N₄₃N₂O₂S₂Ir, 852.2395. found 852.2395. Anal. calcd for C₄₁N₄₃N₂O₂S₂Ir: N, 3.29, C, 57.79, H, 5.09. found: N, 3.27, C, 57.63, H, 5.12.

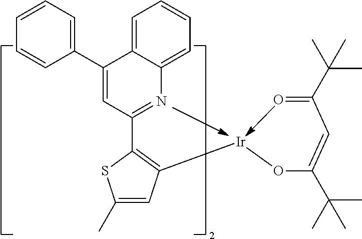

### Iridium(III) bis(2-(5-methylthiophen-2-yl)-4-phenylquinolinato-N,C^{2′})tetramethylheptadionate[(mtpq)₂Ir(tmd)]

dark red solid, yield=57%.

¹H NMR (400 MHz, CD₂Cl₂, δ): 8.27 (d, J=8.8 Hz, 2H), 7.72 (dd, J=1.6 Hz, J=8.4 Hz, 2H), 7.71-7.53 (m, 12H), 7.39-7.30 (m, 4H), 6.13 (s, 2H), 5.16 (s, 1H), 2.41 (s, 6H), 0.76 (s, 18H); ¹³C NMR (100 MHz, CD₂Cl₂, δ): 195.05, 166.30, 157.10, 150.69, 145.67, 138.43, 138.21, 133.99, 130.75, 130.01, 128.96, 126.19, 125.58, 124.51, 117.01, 90.34, 40.98, 27.90, 15.90; HRMS (FAB, m/z): [M+] calcd. for C₅₁H₄₇N₂O₂S₂Ir, 976.2708. found 976.2715. Anal. calcd for C₅₁H₄₇N₂O₂S₂Ir: N, 2.79, C, 63.38, H, 5.12. found: N, 2.85, C, 62.80, H, 4.94.

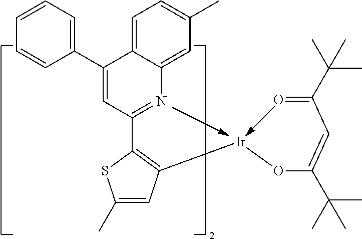

### Iridium(III) bis(7-methyl-2-(5-methylthiophen-2-yl)-4-phenyl quinolinato-N,C^{2′})tetramethylheptadionate[(mtpmq)₂Ir(tmd)]

dark red solid, yield=62%.

¹H NMR (400 MHz, CD₂Cl₂, δ): 8.11 (s, 2H), 7.64-7.52 (m, 12H), 7.52 (s, 2H), 7.18 (d, J=8.4 Hz, 2H), 6.09 (s, 2H), 5.30 (s, 1H), 2.40 (s, 6H), 2.38 (s, 6H), 0.72 (s, 18H); ¹³C NMR (100 MHz, CD₂Cl₂, δ): 195.69, 166.19, 155.76, 150.91, 150.56, 145.26, 141.16, 138.45, 138.35, 133.71, 130.00, 128.92, 126.68, 126.08, 124.68, 122.56, 116.16, 41.06, 28.15, 22.25, 15.88; HRMS (FAB, m/z): [M+] calcd. for C₅₃H₅₁N₂O₂S₂Ir, 1004.3021. found 1004.3015. Anal. calcd for C₅₃H₅₁N₂O₂S₂Ir: N, 2.79, C, 63.38, H, 5.12. found: N, 2.78, C, 63.41, H, 5.71.

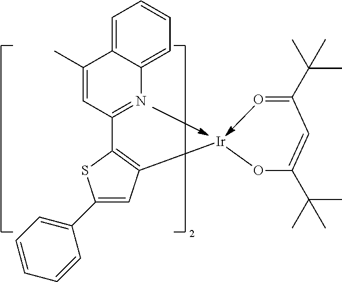

### Iridium(III) bis(4-methyl-2-(5-phenylthiophen-2-yl)quinolinato-N,C^{2′})tetramethylheptadionate[(ptmq)₂Ir(tmd)]

dark red solid, yield=51%.

¹H NMR (400 MHz, CD₂Cl₂, δ): 8.28 (d, J=8.8 Hz, 2H), 7.92-7.90 (m, 2H), 7.62 (s, 2H), 7.46-7.42 (m, 6H), 7.39-7.35 (m, 2H), 7.25-7.21 (m, 4H), 7.18-7.15 (m, 2H), 6.63 (s, 2H), 5.13 (s, 1H), 2.89 (s, 6H), 0.73 (s, 18H); ¹³C NMR (100 MHz, CD₂Cl₂, δ): 194.95, 166.10, 155.86, 149.95, 148.06, 147.01, 140.75, 134.79, 131.28, 130.78, 128.95, 127.90, 126.32, 126.08, 125.90, 124.74, 124.10, 117.63, 90.28, 40.93, 27.91, 19.10; HRMS (FAB, m/z): [M+] calcd. for C₅₁H₄₇N₂O₂S₂Ir, 976.2708. found 976.2712. Anal. calcd for C₅₁H₄₇N₂O₂S₂Ir: N, 2.87, C, 62.74, H, 4.85. found: N, 2.83, C, 62.78, H, 4.89.

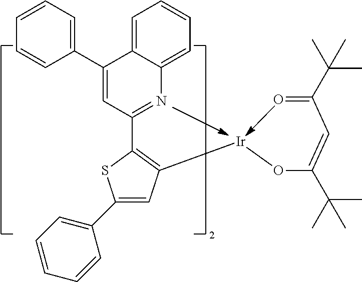

### Iridium(III) bis(2-(5-phenylthiophen-2-yl) 4-phenylquinolinato-N,C^{2′})tetramethylheptadionate[(ptpq)₂Ir(tmd)]

dark red solid, yield=52%.

¹H NMR (400 MHz, CD₂Cl₂, δ): 8.32-8.30 (m, 2H), 7.78-7.75 (m, 2H), 7.69 (s, 2H), 7.66-7.58 (m, 10H), 7.49-7.47 (m, 4H), 7.38-7.34 (m, 4H), 7.24 (td, J=1.6 Hz, J=6.4 Hz, 4H), 7.19-7.17 (m, 2H), 6.78 (s, 2H), 5.14 (s, 1H), 0.76 (s, 18H); ¹³C NMR (100 MHz, CD₂Cl₂, δ): 195.07, 166.13, 156.38, 150.94, 150.63, 148.56, 140.86, 138.14, 134.74, 131.49, 131.00, 130.02, 129.08, 128.00, 126.37, 126.31, 125.80, 124.97, 124.73, 117.33, 90.15, 41.01, 27.90; HRMS (FAB, m/z): [M+] calcd. for C₆₁H₅₁N₂O₂S₂Ir, 1100.3021. found 1100.3024. Anal. calcd for C₆₁H₅₁N₂O₂S₂Ir: N, 2.55, C, 66.58, H, 4.67. found: N, 2.50, C, 66.45, H, 4.67.

### c. Synthesis of Facial Tri-Ligand Iridium Complexes

The chloride-bridged dimer iridium complex (0.3 mmol) was placed into 300 ml two-necked flask with installation of a reflux device, and 150 ml anhydrous acetonitrile was added to dissolve the chloride-bridged dimer iridium complexes. Silver hexafluorophosphate (0.17 g, 0.66 mmol) dissolved in 50 ml anhydrous acetonitrile was then injected into the two-neck reaction flask and then was heated to 70° C. under nitrogen atmosphere with stirring for 2 hours. The silver hexafluorophosphate reactant and the refluxing devices were both foil-coated to keep in dark in process. After completion of the reaction and cooled to room temperature, the reaction product was filtered through Celite to collect the filtrate which was then subjected to the rotary concentrator to remove the solvent and obtain reddish-brown crude product. The crude product was dissolved in a small amount of ethyl ether and then added with a large amount of ester to obtain precipitated yellow-brown to reddish-brown salts of iridium complexes, which was then filtered and collected. The filtrate was then undergone dissolution and elution steps repeatedly until the product was completely collected (yield about 90%). The iridium complex salts (0.5 mmol) were then placed in a 50 ml reactor flask, and 2-(thiophen-2-yl)quinoline derivative (0.55 mmole) and 35 ml o-dichlorobenzene were added under nitrogen, the reaction was heated to 100° C. with stirring for 5 days. After completion of the reaction and cooled to room temperature, the solvent was removed by a vacuum heating method, and then purified with column chromatography using dichloromethane: n-hexane=1:2 as the eluent.

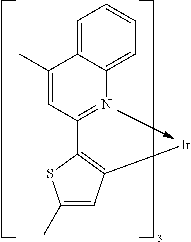

### fac-Iridium(III) tris[2-(5-methylthiophen-2-yl)-4-methylquinolinate-N,C^{2′}] [Ir(mtmq)₃]

red solid, yield=44%.

¹H NMR (400 MHz, CD₂Cl₂, δ): 7.86-7.81 (m, 6H), 7.42 (s, 3H), 7.18 (t, J=7.6 Hz, 3H), 6.69 (t, J=7.6 Hz, 3H), 5.76 (s, 3H), 2.75 (s, 9H), 2.37 (s, 9H); ¹³C NMR (125 MHz, CD₂Cl₂, δ): 161.84, 148.82, 145.85, 144.71, 126.25, 133.71, 129.59, 127.31, 126.29, 124.54, 124.15, 118.65, 19.00, 15.98; HRMS (FAB, m/z): [M+] calcd. for C₄₅H₃₆N₃S₃Ir, 907.1701. found 907.1693. Anal. calcd for C₄₅H₃₆N₃S₃Ir: N, 4.63, C, 59.58, H, 4.00. found: N, 4.67, C, 59.60, H, 4.05.

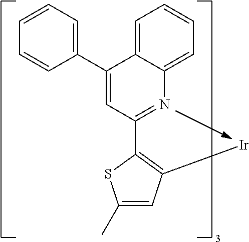

### fac-Iridium(III) tris[2-(5-methylthiophen-2-yl)-4-phenylquinolinate-N,C^{2′}] [Ir(mtpq)₃]

dark red solid, yield=52%.

¹H NMR (400 MHz, CD₂Cl₂, δ): 8.00 (d, J=8.4 Hz, 3H), 7.75 (d, J=8.4 Hz, 3H), 7.61-7.51 (m, 18H), 7.14 (t, J=7.2 Hz, 3H), 6.79 (t, J=8.4 Hz, 3H), 5.87 (s, 3H), 2.41 (s, 9H); ¹³C NMR (100 MHz, CD₂Cl₂, δ): 161.95, 149.92, 149.60, 145.40, 138.20, 136.51, 133.90, 130.09, 129.91, 128.91, 127.24, 126.71, 124.93, 124.50, 118.43 16.07; HRMS (FAB, m/z): [M+] calcd. for C₆₀H₄₂N₃S₃Ir, 1093.2170. found 1093.2170. Anal. calcd for C₆₀H₄₂N₃S₃Ir: N, 3.84, C, 65.91, H, 3.87. found: N, 3.85, C, 66.00, H, 3.91.

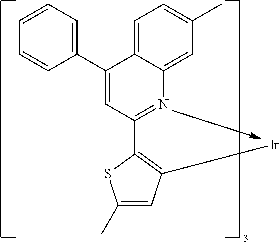

### fac-Iridium(III) tris[7-methyl-2-(5-methylthiophen-2-yl)-4-phenyl quinolinate-N,C^{2′}] [Ir(mtpmq)₃]

dark red solid, yield=49%.

¹H NMR (400 MHz, CD₂Cl₂, δ): 7.85 (s, 3H), 7.60 (d, J=8.4 Hz, 6H), 7.55-7.49 (m, 15H), 6.98 (dd, J=0.8 Hz, J=8.4 Hz, 3H), 5.90 (s, 3H), 2.43 (s, 9H), 1.38 (s, 9H); ¹³C NMR (100 MHz, CD₂Cl₂, δ): 161.79, 149.77, 149.65, 145.15, 140.78, 138.39, 136.54, 134.03, 129.92, 128.89, 128.81, 127.24, 126.53, 126.27, 123.01, 117.57, 20.24, 16.07; HRMS (FAB, m/z): [M+] calcd. for C₆₃H₄₈N₃S₃Ir, 1135.2640. found 1135.2638. Anal. calcd for C₆₃H₄₈N₃S₃Ir: N, 3.70, C, 66.64, H, 4.26. found: N, 3.65, C, 66.78, H, 4.28.

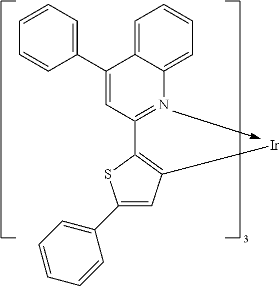

### fac-Iridium(III) tris[2-(5-phenylthiophen-2-yl) 4-phenylquinolinate-N,C^{2′}] [Ir(ptpq)₃]

dark red solid, yield=43%.

¹H NMR (400 MHz, CD₂Cl₂, δ): 8.08 (d, J=8.4 Hz, 3H), 7.79 (d, J=8.0 Hz, 3H), 7.70 (s, 3H), 7.63-7.61 (m, 6H), 7.59-7.50 (m, 9H), 7.27-7.24 (m, 6H), 7.21-7.16 (m, 6H), 6.85 (td, J=1.2 Hz, J=7.6 Hz, 3H), 5.59 (s, 3H); ¹³C NMR (100 MHz, CD₂Cl₂, δ): 161.80, 160.84, 150.28, 149.63, 148.32, 138.73, 138.05, 134.92, 131.32, 130.13, 128.98, 128.93, 127.86, 127.38, 126.88, 126.32, 125.36, 124.93, 118.74; HRMS (FAB, m/z): [M+] calcd. for C₇₅H₄₈N₃S₃Ir, 1279.2640. found 1279.2646. Anal. calcd for C₇₅H₄₈N₃S₃Ir: N, 3.28, C, 70.40, H, 3.78. found: N, 3.15, C, 70.45, H, 3.75.

TABLE 1
The optical physical properties of the iridium complexes:

| complexes | (mtq)₂Ir(acac) | (mtmq)₂Ir(acac) | (4mtmq)₂Ir(acac) |
|---|---|---|---|
| λₘₐₓ (nm) | 626 | 616 | 614 |
| Φₑₘ^{[a]} | 0.19 | 0.27 | 0.17 |
| complexes | (mtpq)₂Ir(acac) | (mtpmq)₂Ir(acac) | (ptmq)₂Ir(acac) |
| λₘₐₓ (nm) | 635 | 633 | 666 |
| Φₑₘ^{[a]} | 0.33 | 0.30 | 0.02 |
| complexes | (ptpq)₂ Ir(acac) | (mtmq)₂ Ir(tmd) | (mtpq)₂Ir(tmd) |
| λₘₐₓ (nm) | 675 | 621 | 640 |
| Φₑₘ^{[a]} | 0.01 | 0.16 | 0.15 |
| complexes | (mtpmq)₂Ir(tmd) | (ptmq)₂Ir(tmd) | (ptpq)₂Ir(tmd) |
| λₘₐₓ (nm) | 639 | 671 | 678 |
| Φₑₘ^{[a]} | 0.24 | 0.04 | 0.07 |
| complexes | (mtmq)₃Ir | (mtpq)₃Ir | (mtpmq)₃Ir |
| λₘₐₓ (nm) | 596 | 613 | 608 |
| Φₑₘ^{[a]} | 0.14 | 0.38 | 0.35 |
| complexes | (ptpq)₃Ir | | |
| λₘₐₓ (nm) | 657 | | |
| Φₑₘ^{[a]} | 0.08 | | |

^{[a]}Φₑₘ (quantum yield) is measured at 298K, in 10⁻⁵M oxygen-free toluene solution, where Ir(piq)₃ (Φₑₘ = 0.26) is the control.

Refer to Table 1, which illustrates the optical physical characteristics of iridium of the present invention. The iridium complexes of the present invention are red phosphorescent materials having emitting wavelength ranging from 596 nm to 675 nm. Here, the quantum efficiency of (mtpq)₃Ir and (mtpmq)₃Ir may reach 0.38 and 0.35, respectively and is higher than conventional similar light color material Ir(piq)₃(Iridium(III)tris(1-phenyl-isoquinolinato-C2,N), used in common reference by near 50%. Complex (mtpq)₂Ir(acac) has emitting wavelength at 635 nm and has quantum efficiency of 0.33, meanwhile.

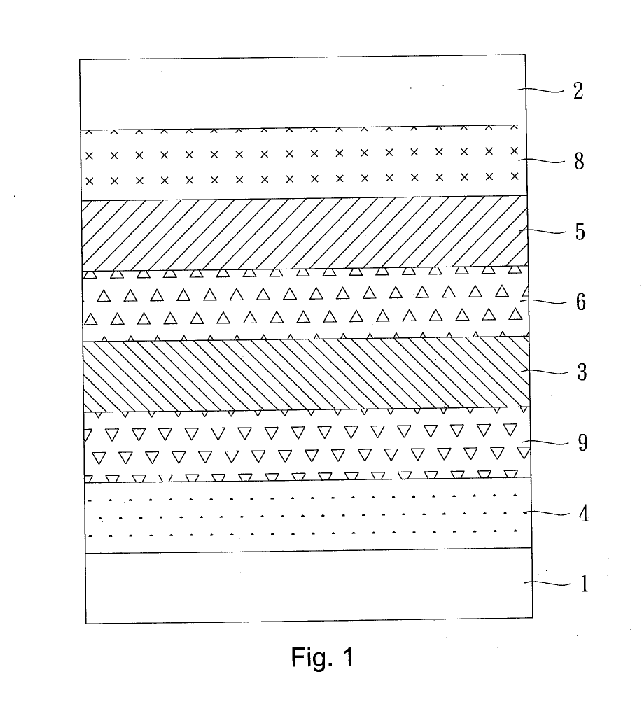

Besides, referring to FIG. 1, FIG. 1 is a schematic diagram illustrating the structure of the organic light emitting diode using the iridium complex according to an embodiment of the present invention. The organic light emitting diode comprises an anode 1, a cathode 2 and a light-emitting layer 3 arranged between the anode 1 and the cathode 2. The light-emitting layer 3 comprises the chemical compounds provided by the present invention and is formed by doping light emitting materials into the host materials. The structure of the light-emitting materials also comprises a hole transport layer 4, an electron blocking layer 9, an light-emitting layer 3, a hole blocking layer 6, an electron transporting layer 5 and an electron injection layer 8 formed sequentially from bottom to top on the anode 1. Thickness of each layer displayed in FIG. 1 is not representative of actual size. Among these layers, the electron blocking layer 9, the hole blocking layer 6, and the electron injection layer 8 are optionally involved. The iridium complex of the present invention can be used as host materials or dopant of the light emitting layer 3.

For example, the organic light emitting diode of the present invention can be a red phosphorescent OLED, a green phosphorescent OLED or an orange phosphorescent OLED.

### Exemplified Electroluminescent Device Structure

Light emitting devices using different materials are exemplified here for testing and comparing properties thereof. Among these devices, ITO is used as substrates; electrode materials comprises LiF/Al; light-emitting materials comprises Ir(piq)₃(Iridium(III)tris(1-phenyl-isoquinolinato-C2,N); the electron transport layer comprises BCP (2,9-dimethyl-4,7-diphenyl-[1,10]phenanthroline) and Alg₃ (tris(8-hydroxyquinoline)aluminum(III), which are also adequate for electron blocking layer or for both; hole transport layer comprises NPB (4,4′-bis[N-(1-naphthyl)-N-phenyl-amino]bipheny) and TCTA (4,4′,4″-tri(N-carbazolyl)triphenylamine)), which are also adequate for electron blocking layer or for both.

### Comparison of Device Performance

TABLE 2
Performance of Red OLED Device

| | Lₘₐₓ | | | ηₚ, ₘₐₓ | |
|---|---|---|---|---|---|
| | [Cd/ | ηₑₓₜ, ₘₐₓ | η_{c}, ₘₐₓ | [lm/ | CIE (x,y) |
| dopant | m², V] | [%, V] | [cd/A, V] | W, V] | at 8 V |
| (13) | 29819, | 12.8, | 19.1, | 9.9, | |
| US | 14.0 | 6.8 | 6.8 | 5.4 | |
| 20050025995* | | | | | |
| (14) | 44355, | 7.3, | 13.8, | 3.6, | |
| US | 15.0 | 11.9 | 11.9 | 11.2 | |
| 20050025995* | | | | | |
| (4mtmq)₂Ir(acac) | 43277, | 15.4, | 22.9, | 18.3, | (0.67, 0.33) |
| | 14.5 | 5.5 | 5.5 | 3.5 | |
| (mtmq)₂Ir(acac) | 36202, | 20.0, | 24.4, | 18.3, | (0.68, 0.32) |
| | 14.5 | 5.5 | 5.5 | 4.0 | |
| (mtq)₂Ir(acac) | 28714, | 18.6, | 17.7, | 13.8, | (0.69, 0.31) |
| | 15.5 | 5.5 | 5.5 | 4.0 | |
| (mtpq)₂Ir(acac) | 29522, | 28.2, | 19.0, | 14.4, | (0.70, 0.30) |
| | 16.0 | 5.0 | 5.0 | 4.0 | |
| (mtpmq)₂Ir(acac) | 31895, | 26.8, | 19.4, | 14.6, | (0.70, 0.30) |
| | 15.5 | 5.0 | 5.5 | 4.0 | |
| (ptmq)₂Ir(acac) | 2785, | 8.4, | 1.7, | 1.3, | (0.71, 0.28) |
| | 14.5 | 4.0 | 4.0 | 4.0 | |
| (ptpq)₂Ir(acac) | 2853, | 14.7, | 1.9, | 1.5, | (0.71, 0.28) |
| | 15.0 | 4.0 | 4.0 | 4.0 | |
| (mtmq)₂Ir(tmd) | 32914, | 25.3, | 30.9, | 24.3, | (0.68, 0.32) |
| | 14.0 | 4.0 | 4.0 | 4.0 | |
| (mtpq)₂Ir(tmd) | 25604, | 27.1, | 18.2, | 14.3, | (0.70, 0.30) |
| | 14.5 | 4.0 | 4.0 | 4.0 | |
| (mtpmq)₂Ir(tmd) | 27998, | 23.1, | 15.5, | 11.7, | (0.70, 0.30) |
| | 14.5 | 5.5 | 5.5 | 3.5 | |
| (ptmq)₂Ir(tmd) | 3171, | 7.0, | 1.2, | 0.8, | (0.72, 0.28) |
| | 15.5 | 5.5 | 6.5 | 4.5 | |
| (ptpq)₂Ir(tmd) | 3294, | 14.0, | 1.6, | 1.1, | (0.72, 0.28) |
| | 15.5 | 5.5 | 5.5 | 4.5 | |
| (mtmq)₃Ir | 57636, | 16.6, | 35.2, | 24.2, | (0.63, 0.37) |
| | 14.5 | 6.0 | 4.0 | 4.0 | |
| (mtpq)₃Ir | 54601, | 24.7, | 36.0, | 29.3, | (0.66, 0.34) |
| | 16.0 | 6.0 | 6.0 | 4.0 | |
| (mtpmq)₃Ir | 62926, | 25.4, | 41.7, | 30.2, | (0.66, 0.34) |
| | 15.5 | 5.5 | 4.0 | 4.0 | |
| (ptpq)₃Ir | 5033, | 11.8, | 3.6, | 2.4, | (0.71, 0.29) |
| | 15.5 | 5.5 | 5.5 | 4.5 | |
| (piq)₂Ir(acac) | 66535, | 23.2, | 29.1, | 22.4, | (0.67, 0.33) |
| [ref] | 16.0 | 5.0 | 5.0 | 4.0 | |
| (13) [ref]* | 50560, | 22.4, | 33.1, | 25.4, | (0.67, 0.33) |
| | 14.5 | 5.0 | 5.0 | 4.0 | |

*device configuration of US patent application 20050025995: ITO/NPB/CBP: (13)or(14)/BCP/Alq₃/Mg:Ag/Ag
device configuration of the present invention: ITO/NPB/TCTA/BIQS(Bis(4-(6H-indolo[2,3-b]quinoxalin-6-yl)phenyl)diphenylsilane):dopant/BCP/Alq₃/LiF/Al
** Lₘₐₓ: maximum luminescence); ηₑₓₜ: maximum external quantum efficiency; η_{c}: maximum current efficiency; ηₚ: maximum power efficiency

Refer to Table 2, which shows performance of the red organic light-emitting diodes. The differences between complexes of US20050025995 and the present invention lie in formula (1) wherein R6 or R7 are modified with functional groups. US 20050025995 illustrates that the device adopting compound (13) may achieve the maximum external quantum efficiency of 12.8%, a current efficiency of 19.1 cd/A, the energy efficiency of 9.9 lm/W. In a up-to-date test with improved device configuration and materials, the maximum external quantum efficiency and current efficiency can be increased by approximately 80%, and the energy efficiency can be improved to 3 times more; the device adopting compound (13), under the same conditions, increased maximum current efficiency and energy efficiency by approximately 10% in comparison to devices using (piq)₂Ir(acac) in some references.

Therefore, as seen from the above data, the iridium complexes of the present invention are modified with functional group at R6 or R7 position represented in formula (1) and resulted in enhanced performance in comparison to US 20050025995 complexes.

When used in the devices, the compounds (mtpq)₃Ir and (mtpmq)₃Ir of the invention are provided with emitting light color and capable of enhancing the current efficiency or energy efficiency of the devices to 8-25%. In addition to these improvements in efficiency, some phosphorescent materials in this series such as (mtpq)₂Ir(acac), (mtpmq)₂Ir(acac), (mtpq)₂Ir(tmd), (mtpmq)₂Ir(tmd) are so closer to the real red color, having CIE color coordinates (0.70, 0.30), providing a wider display capabilities in color gamut, and reaching the scope of the NTSC 115% (Note: the current display is NTSC 72% in general) as well as excellent performance in maximum external quantum efficiency.

In addition, compounds (ptpq)₂Ir(tmd), (ptpq)₃Ir have maximum emitting wavelength at nearly 700 nm and are provided with potential in applications such as near-infrared light devices including biomedical imaging techniques and other applications.

In summary, the iridium complexes of the present invention are provided with good thermal stability, chemical stability and achieve high external quantum efficiency, current efficiency in red phosphorescent OLED devices and thus result in improved performance of red phosphorescent OLED devices.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. An iridium complex represented by formula (1): 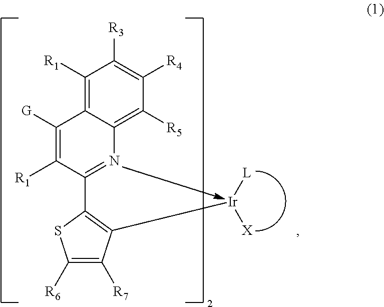
wherein groups L and X are linked in an arch to form a ligand represented by Ar₁-Ar₂, L is N or O and X is C, N or O, Ar₁ is a non-substituted or substituted N-heterocyclic ring, Ar₂ is a non-substituted or substituted aromatic ring, a non-substituted or substituted N-heterocyclic ring or a non-substituted or substituted S-heterocyclic ring, or Ar₁ and Ar₂ together are 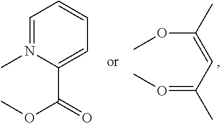
wherein each of substituents of Ar₁ and Ar₂, G, R₁ to R₇ is a member independently selected from the group consisting of H, halo, cyano, amino, substituted or non-substituted C₁-C₁₀ alkyl, substituted or non-substituted C₂-C₁₀ alkenyl, substituted or non-substituted C₂-C₁₀ alkynyl, substituted or non-substituted C₃-C₂₀ cycloalkyl, substituted or non-substituted C₃-C₂₀ cycloalkenyl, substituted or non-substituted C₁-C₂₀ heterocycloalkyl, substituted or non-substituted C₁-C₂₀ heterocycloalkenyl, substituted or non-substituted aryl and substituted or non-substituted heteroaryl and wherein at least one of R₆ and R₇ is not hydrogen.

2. The iridium complex as claimed in claim 1, wherein R6 is selected from a group consisting of substituted or non-substituted C₁-C₁₀ alkyl, substituted or non-substituted C₂-C₁₀ alkenyl, substituted or non-substituted C₂-C₁₀ alkynyl, and substituted or non-substituted aryl.

3. The iridium complex as claimed in claim 1, wherein R6 is selected from a group consisting of substituted or non-substituted C₁-C₁₀ alky and substituted or non-substituted phenyl group.

4. The iridium complex as claimed in claim 1, wherein R7 is selected from a group consisting of substituted or non-substituted C₁-C₁₀ alkyl, substituted or non-substituted C₂-C₁₀ alkenyl, substituted or non-substituted C₂-C₁₀ alkynyl, and substituted or non-substituted aryl.

5. The iridium complex as claimed in claim 1, wherein R7 is selected from a group consisting of substituted or non-substituted C₁-C₁₀ alky and substituted or non-substituted phenyl group.

6. The iridium complex as claimed in claim 1, wherein G is selected from a group consisting of substituted or non-substituted C₁-C₁₀ alky and substituted or non-substituted phenyl group.

7. The iridium complex as claimed in claim 1, wherein Ar₁-Ar₂ is a ĈN or ÔO ligand.

8. The iridium complex as claimed in claim 1, represented by formula (2) or (3), 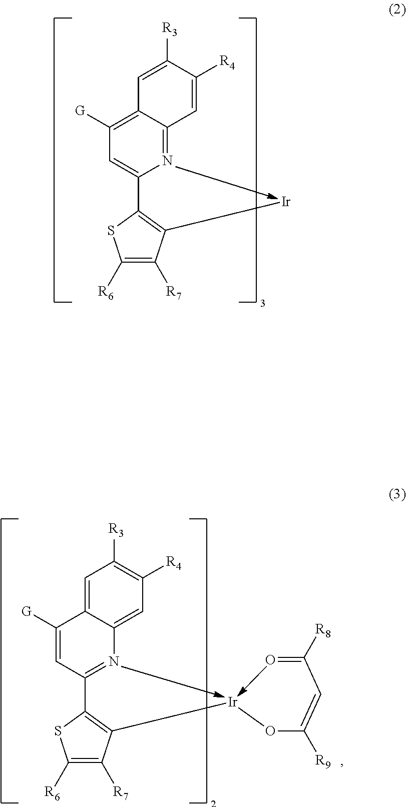
wherein each of R₈ and R₉ is a member independently selected from the group consisting of H, halo, cyano, amino, substituted or non-substituted C₁-C₁₀ alkyl, substituted or non-substituted C₂-C₁₀ alkenyl, substituted or non-substituted C₂-C₁₀ alkynyl, substituted or non-substituted C₃-C₂₀ cycloalkyl, substituted or non-substituted C₃-C₂₀ cycloalkenyl, substituted or non-substituted C₁-C₂₀ heterocycloalkyl, substituted or non-substituted C₁-C₂₀ heterocycloalkenyl, substituted or non-substituted aryl and substituted or non-substituted heteroaryl.

9. An organic light emitting diode, comprising:
a cathode;
an anode; and
a light-emitting layer arranged between the anode and the cathode, wherein the light-emitting layer represented by formula (1): 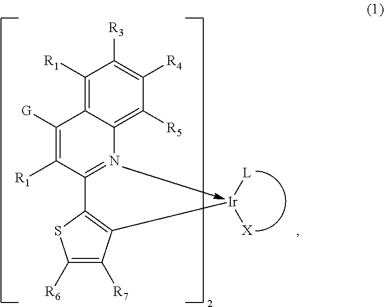
wherein groups L and X are linked in an arch to form a ligand represented by Ar₁-Ar₂, L is N or O and X is C, N or O, Ar₁ is a non-substituted or substituted N-heterocyclic ring, Ar₂ is a non-substituted or substituted aromatic ring, a non-substituted or substituted N-heterocyclic ring or a non-substituted or substituted S-heterocyclic ring, or Ar₁ and Ar₂ together are 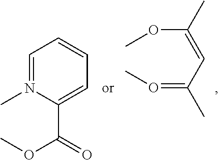
wherein each of substituents of Ar₁ and Ar₂, G, R₁ to R₇ is a member independently selected from the group consisting of H, halo, cyano, amino, substituted or non-substituted C₁-C₁₀ alkyl, substituted or non-substituted C₂-C₁₀ alkenyl, substituted or non-substituted C₂-C₁₀ alkynyl, substituted or non-substituted C₃-C₂₀ cycloalkyl, substituted or non-substituted C₃-C₂₀ cycloalkenyl, substituted or non-substituted C₁-C₂₀ heterocycloalkyl, substituted or non-substituted C₁-C₂₀ heterocycloalkenyl, substituted or non-substituted aryl and substituted or non-substituted heteroaryl and wherein at least one of R₆ and R₇ is not hydrogen.

10. The organic light emitting diode as claimed in claim 9, wherein R6 is selected from a group consisting of substituted or non-substituted C₁-C₁₀ alkyl, substituted or non-substituted C₂-C₁₀ alkenyl, substituted or non-substituted C₂-C₁₀ alkynyl, and substituted or non-substituted aryl.

11. The organic light emitting diode as claimed in claim 9, wherein R6 is selected from a group consisting of substituted or non-substituted C₁-C₁₀ alky and substituted or non-substituted phenyl group.

12. The organic light emitting diode as claimed in claim 9, wherein R7 is selected from a group consisting of substituted or non-substituted C₁-C₁₀ alkyl, substituted or non-substituted C₂-C₁₀ alkenyl, substituted or non-substituted C₂-C₁₀ alkynyl, and substituted or non-substituted aryl.

13. The organic light emitting diode as claimed in claim 9, wherein R7 is selected from a group consisting of substituted or non-substituted C₁-C₁₀ alky and substituted or non-substituted phenyl group.

14. The organic light emitting diode as claimed in claim 9, wherein G is selected from a group consisting of substituted or non-substituted C₁-C₁₀ alky and substituted or non-substituted phenyl group.

15. The organic light emitting diode as claimed in claim 9, wherein Ar₁-Ar₂ is a ĈN or ÔO ligand.

16. The organic light emitting diode as claimed in claim 9, wherein the iridium complex is represented by formula (2) or (3), 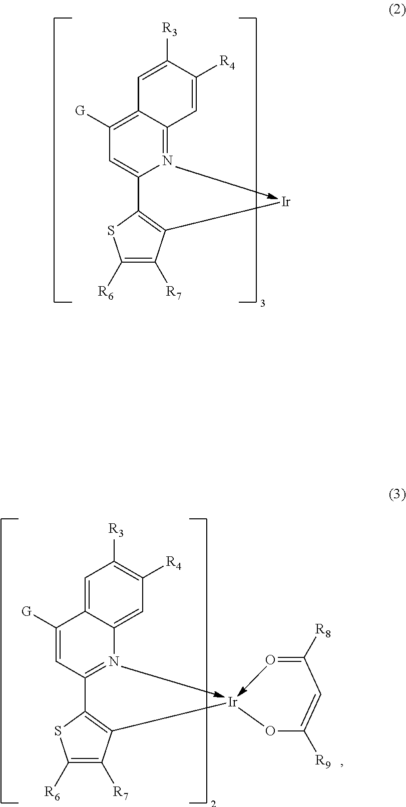
wherein each of R₈ and R₉ is a member independently selected from the group consisting of H, halo, cyano, amino, substituted or non-substituted C₁-C₁₀ alkyl, substituted or non-substituted C₂-C₁₀ alkenyl, substituted or non-substituted C₂-C₁₀ alkynyl, substituted or non-substituted C₃-C₂₀ cycloalkyl, substituted or non-substituted C₃-C₂₀ cycloalkenyl, substituted or non-substituted C₁-C₂₀ heterocycloalkyl, substituted or non-substituted C₁-C₂₀ heterocycloalkenyl, substituted or non-substituted aryl and substituted or non-substituted heteroaryl.

17. The organic light emitting diode as claimed in claim 9, wherein the organic light emitting diode is a red phosphorescent organic light emitting diode.

18. The organic light emitting diode as claimed in claim 9, wherein the organic light emitting diode is a near-infrared phosphorescent organic light emitting diode.

19. The organic light emitting diode as claimed in claim 9, wherein the iridium complex is a host material or a dopant.
